(19) United States
(12) Patent Application Publication
(10) Pub. No.: US 2024/0322795 A1
(43) Pub. Date: Sep. 26, 2024

(54) TRANSMIT (TX) RECEIVE (RX) PHASED ARRAY SYSTEM

(71) Applicant: QUALCOMM INCORPORATED, San Diego, CA (US)

(72) Inventors: Muhammad HASSAN, San Diego, CA (US); Chuan WANG, San Diego, CA (US); Anosh DAVIERWALLA, San Diego, CA (US)

(21) Appl. No.: 18/189,654

(22) Filed: Mar. 24, 2023

(51) Int. Cl. H03H 11/16; H01Q 3/36; H03F 3/19

(52) U.S. Cl. CPC H03H 11/16; H03F 3/24; H03F 2200/294; H03F 2200/451

(57) ABSTRACT

A millimeter wave (mmW) communication system located on a millimeter wave integrated circuit (MMW-IC) includes a phase shifter selectively connected to a receive path by a first electromagnetic (EM) element and selectively connected to a transmit path by a second EM element, the first EM element configured to receive a transmit signal and configured to receive a receive signal from a low noise amplifier (LNA), the second EM element configured to receive a phase shifted transmit signal or a phase shifted receive signal from the phase shifter, and wherein the second EM element is configured to selectively provide the phase shifted transmit signal to a power amplifier on the mmW-IC and the phase shifted receive signal to receive signal processing circuitry located off of the mmW-IC.

### FIELD

The present disclosure relates generally to electronics, and more specifically to phase shifters in a transceiver.

### BACKGROUND

Wireless communication devices and technologies are becoming ever more prevalent, as are communication devices that operate at millimeter-wave (mmW) and sub-terahertz (subTHz) frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications may communicate using millimeter wave (mmW) frequency signals and/or sub-THz frequencies and may use what is referred to as a zero intermediate frequency (ZIF) architecture or a low-IF architecture.

Transceivers used in 5G communication systems may use what is referred to as beamforming to increase system capacity. Beamforming generally uses individual transmit and receive elements where a phase shifter alters the phase of the signal. Typically, many such elements and phase shifters are implemented in such a system. Typically, each TX/RX element uses two phase shifters, one for transmit and one for receive.

A typical system architecture may implement four phase shifters for two adjacent TX/RX elements. Each phase shifter may comprise a hybrid quadrature generator (HQG) and a combining circuit, and as a result occupies large area on a circuit.

Therefore, it would be desirable to minimize the number of phase shifters in such systems.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a millimeter wave (mmW) communication system located on a millimeter wave integrated circuit (MMW-IC) including a phase shifter selectively connected to a receive path by a first electromagnetic (EM) element and selectively connected to a transmit path by a second EM element, the first EM element configured to receive a transmit signal and configured to receive a receive signal from a low noise amplifier (LNA), the second EM element configured to receive a phase shifted transmit signal or a phase shifted receive signal from the phase shifter, and wherein the second EM element is configured to selectively provide the phase shifted transmit signal to a power amplifier on the mmW-IC and the phase shifted receive signal to receive signal processing circuitry located off of the mmW-IC.

Another aspect of the disclosure provides a method for phase shifting signals including selectively applying a transmit signal or a receive signal to a shared phase shifter, phase shifting the transmit signal or the receive signal, and selectively applying the phase shifted transmit signal to a power amplifier or selectively applying the phase shifted receive signal to a phased array output.

Another aspect of the disclosure provides a device for signal phase shifting including means for selectively applying a transmit signal or a receive signal to a shared phase shifter, means for phase shifting the transmit signal or the receive signal, and means for selectively applying the phase shifted transmit signal to a power amplifier or selectively applying the phase shifted receive signal to a phased array output.

Another aspect of the disclosure provides a phased array element including receive circuitry, transmit circuitry, a first electromagnetic (EM) element coupled to the receive circuitry, a second EM element coupled to the transmit circuitry, and a phase shifter coupled between the first EM element and the second EM element, wherein the phased array element is configured such that the phase shifter is shared by the receive circuitry and the transmit circuitry.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a block diagram of two transmit (TX) and receive (RX) elements in a phased array system.

FIGS. 4A and 4B are schematic diagrams of an embodiment of a tri-coil of FIG. 3.

FIGS. 5A and 5B are schematic diagrams of an embodiment of a tri-coil of FIG. 3.

FIG. 6 is a flow chart describing an example of the operation of a method for processing signals.

FIG. 7 is a functional block diagram of an apparatus for processing signals.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, a TX/RX radio architecture has a single phase shifter that can be shared between transmit and receive elements, thus reducing circuit area.

In accordance with an exemplary embodiment, a TX/RX radio architecture has a phase shifter that is implemented in a single direction where transit and receive signals are selectively routed through the phase shifter.

In accordance with an exemplary embodiment, a TX/RX radio architecture uses one or more tri-coil electromagnetic (EM) structures for combining signals including switching that provides impedance matching and lowers the loading on transmit and receive elements.

In accordance with an exemplary embodiment, a TX/RX radio architecture can be single-ended in a receive mode after the phase shifter.

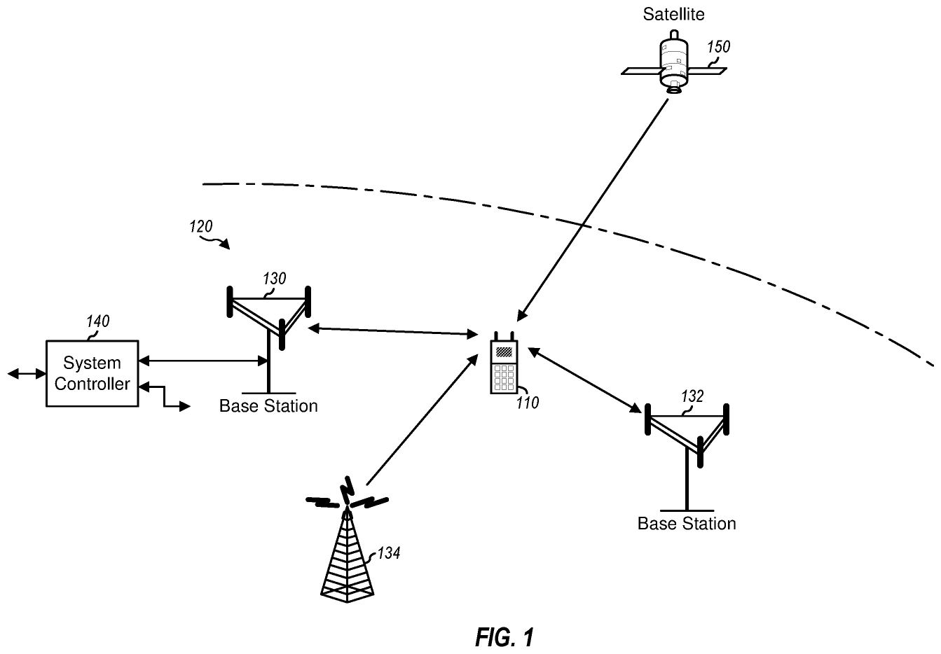

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS)), or a satellite that can receive signals from the wireless device 110, etc). Wireless device 110 may support one or more radio technologies for wireless communication such as LTE, WCDMA, CDMA 1X, EVDO, TD-SCDMA, GSM, 802.11. 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

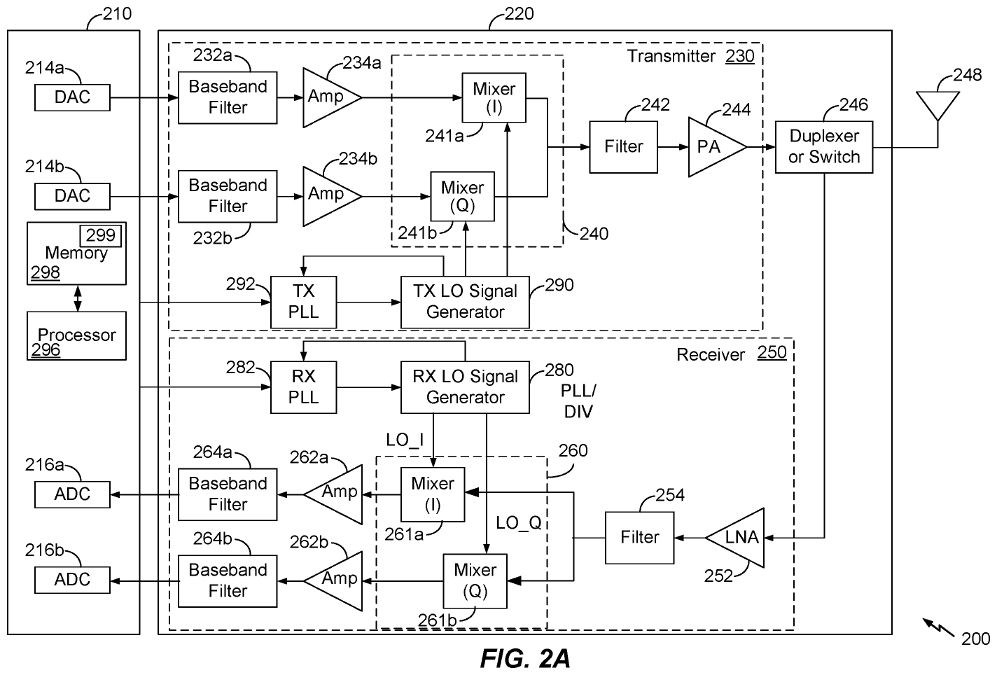

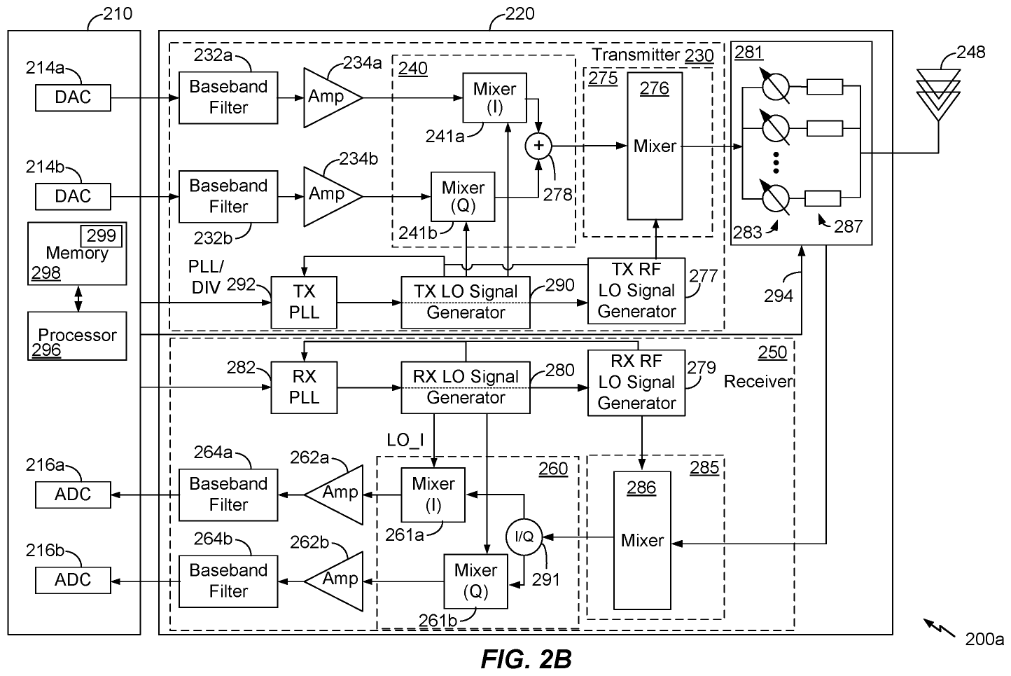

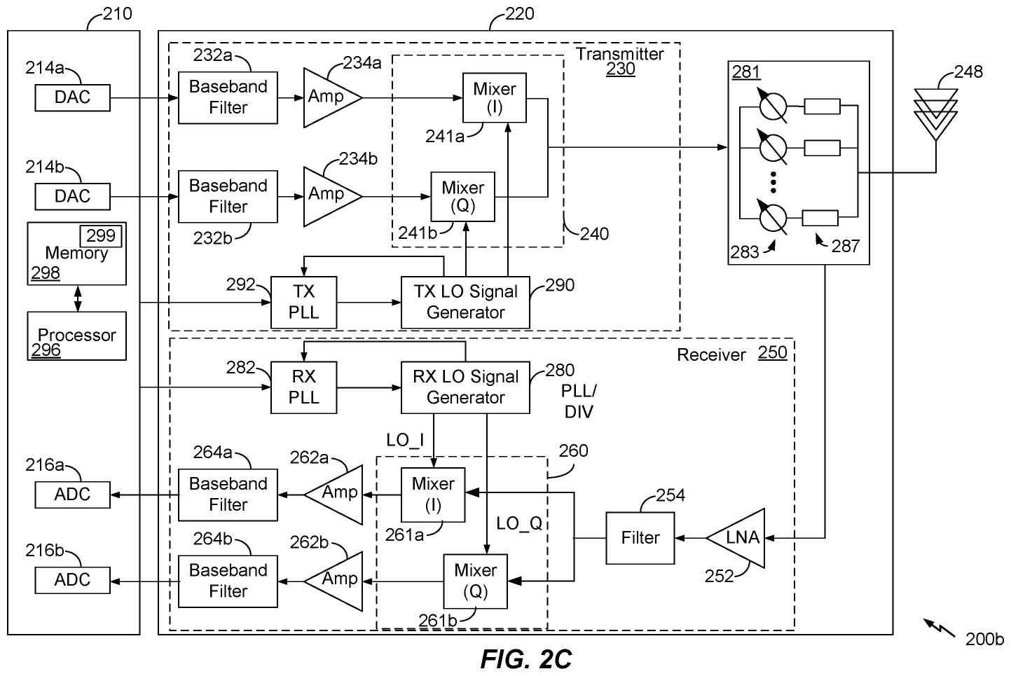

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the TX LO leakage calibration circuit described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A. TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or super-heterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may be configured to provide an IF signal to an upconverter 275. In an exemplary embodiment, the upconverter 275 may comprise an upconversion mixer 276. The summing function 278, which may be part of the upconverter 240 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented. In an exemplary embodiment, the phase shift circuitry 281 may be part of or may be located on a millimeter wave integrated circuit (mmW-IC).

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. An I/Q generation function 291 in the downconverter 260 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHZ.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

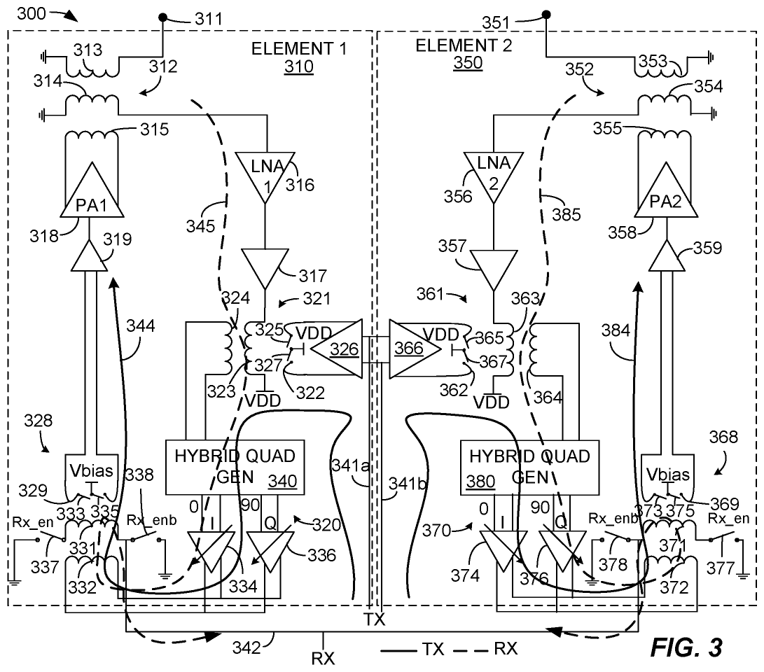

FIG. 3 is a block diagram 300 of two transmit (TX) and receive (RX) elements in a phased array system, for example as may be included in phase shift circuitry 281. The elements of diagram 300 may be located on a millimeter wave integrated circuit (mmW-IC). A first element 310, which may be an example of a phased array element 287, may comprise an electromagnetic (EM) element 312 configured to couple the TX and RX paths of the first element 310 to an antenna or antenna port 311. In an exemplary embodiment, the EM element 312 may comprise a first inductive element 313, a second inductive element 314 and a third inductive element 315. If the EM element 312 is implemented as a transformer (or as a magnetic circuit referred to as a tri-coil), then the first inductive element 313 may be a primary side (or primary coil), the second inductive element 314 may be a secondary side (or secondary coil) and the third inductive element 315 may be a tertiary coil. In an exemplary embodiment, the terms primary, secondary and tertiary are not intended to signify signal direction as a transmit signal may traverse the EM element 312 in a direction opposite that of a receive signal.

In an exemplary embodiment, the first element 310 may also comprise a power amplifier (PA) 318, a driver amplifier (DA) 319 and an EM element 328. In some embodiments, more than two stages of transmit signal amplification may be implemented. In an exemplary embodiment, the EM element 328 may comprise a first inductive element 332, a second inductive element 331 and a third inductive element 329. If the EM element 328 is implemented as a transformer (or as a magnetic circuit referred to as a tri-coil), then the first inductive element 332 may be a primary side (or primary coil), the second inductive element 331 may be a secondary side (or secondary coil) and the third inductive element 329 may be a tertiary coil. In an exemplary embodiment, the third inductive element 329 may comprise switches 333 and 335 located on either side of and close to a center tap of the third inductive element 329. In an exemplary embodiment, the center tap may be connected to bias voltage, Vbias.

In an exemplary embodiment, the first element 310 may also comprise RX circuitry including a first stage low noise amplifier (LNA) 316 and a second stage LNA 317, although a different number of LNA stages may be implemented. An output of the second stage LNA 317 may be provided to an EM element 321. In an exemplary embodiment, the EM element 321 may comprise a first inductive element 322, a second inductive element 323 and a third inductive element 324. If the EM element 321 is implemented as a transformer (or as a magnetic circuit referred to as a tri-coil), then the first inductive element 322 may be a primary side (or primary coil), the second inductive element 323 may be a secondary side (or secondary coil) and the third inductive element 324 may be a tertiary coil. In an exemplary embodiment, the terms primary, secondary and tertiary are not intended to signify signal direction as a transmit signal may traverse the EM element 321 such that the first inductive element 322 may be considered the primary coil and the third inductive element 324 may be considered the secondary coil. However, a receive signal may traverse the EM element 321 such that the second inductive element 323 may be considered the primary coil and the third inductive element 324 may be considered the secondary coil. In an exemplary embodiment, a side of the second inductive element 323 opposite the second stage LNA 317 may be connected to a system voltage, VDD. In an exemplary embodiment, the first inductive element 322 may comprise switches 325 and 327 located on either side of and close to a center tap of the first inductive element 322. In an exemplary embodiment, the center tap may be connected to a system voltage, VDD.

In an exemplary embodiment, the first element 310 includes a phase shifter 320 coupled between the EM element 321 and the EM element 328. The phase shifter 320 is illustrated as comprising a hybrid quadrature generator (HQG) 340, and variable gain amplifiers (VGAs) 334 and 336, although other implementations of phase shifter may be used. For example, a phase shifter having a polyphase filter and active or passive VGAs may be implemented. In an exemplary embodiment, the HQG 340 may be configured to create an in phase (I) signal and a quadrature (Q) signal separated by 90 degrees. For example, the VGA 334 may be configured to operate on an in phase signal and the VGA 336 may be configured to operate on a quadrature signal. In an exemplary embodiment, a vector modulator driver (VMDR) 326 may be coupled to the EM element 321 and configured to operate on a transmit signal, for example to provide a differential transmit signal to opposite ends of the inductive element 322.

In an exemplary embodiment, outputs of the VGA 334 are provided to opposite sides of the inductive element 332 and outputs of the VGA 336 are provided to opposite sides of the inductive element 332 of the EM element 328. In an exemplary embodiment a switch 337 may be connected between one end of the inductive element 331 and ground, and a switch 338 may be connected between the other end of the inductive element 331 and ground. The switch 337 may be controlled by a control signal Rx_en and the switch 338 may be controlled by a control signal Rx_enb such that when the switch 337 is conductive, the switch 338 is non-conductive and when the switch 338 is conductive, the switch 337 is non-conductive. The complementary control signals Rx_en and Rx_enb may be provided by the data processor (210, FIG. 2C), or by another controller.

A second element 350, which may be another example of a phased array element 287, may comprise an electromagnetic (EM) element 352 configured to couple the TX and TX paths of the second element 350 to an antenna or antenna port 351. In an exemplary embodiment, the EM element 352 may comprise a first inductive element 353, a second inductive element 354 and a third inductive element 355. If the EM element 352 is implemented as a transformer (or as a magnetic circuit referred to as a tri-coil), then the first inductive element 353 may be a primary side (or primary coil), the second inductive element 354 may be a secondary side (or secondary coil) and the third inductive element 355 may be a tertiary coil. In an exemplary embodiment, the terms primary, secondary and tertiary are not intended to signify signal direction as a transmit signal may traverse the EM element 352 in a direction opposite that of a receive signal.

In an exemplary embodiment, the second element 350 may also comprise a power amplifier (PA) 358, a driver amplifier 359 and an EM element 368. In some embodiments, more than two stages of transmit signal amplification may be implemented. In an exemplary embodiment, the EM element 368 may comprise a first inductive element 372, a second inductive element 371 and a third inductive element 369. If the EM element 368 is implemented as a transformer (or as a magnetic circuit referred to as a tri-coil), then the first inductive element 372 may be a primary side (or primary coil), the second inductive element 371 may be a secondary side (or secondary coil) and the third inductive element 399 may be a tertiary coil. In an exemplary embodiment, the third inductive element 369 may comprise switches 373 and 375 located on either side of and close to a center tap of the third inductive element 369. In an exemplary embodiment, the center tap may be connected to a bias voltage, Vbias.

In an exemplary embodiment, the second element 350 may also comprise RX circuitry including a first stage low noise amplifier (LNA) 356 and a second stage LNA 357, although a different number of LNA stages may be implemented. An output of the second stage LNA 357 may be provided to an EM element 361. In an exemplary embodiment, the EM element 361 may comprise a first inductive element 362, a second inductive element 363 and a third inductive element 364. If the EM element 361 is implemented as a transformer (or as a magnetic circuit referred to as a tri-coil), then the first inductive element 362 may be a primary side (or primary coil), the second inductive element 363 may be a secondary side (or secondary coil) and the third inductive element 364 may be a tertiary coil. In an exemplary embodiment, the terms primary, secondary and tertiary are not intended to signify signal direction as a transmit signal may traverse the EM element 361 such that the first inductive element 362 may be considered the primary coil and the inductive element 364 may be considered the secondary coil. However, a receive signal may traverse the EM element 361 such that the inductive element 363 may be considered the primary coil and the inductive element 364 may be considered the secondary coil. In an exemplary embodiment, a side of the second inductive element 363 opposite the second stage LNA 357 may be connected to a system voltage, VDD. In an exemplary embodiment, the first inductive element 362 may comprise switches 365 and 367 located on either side of and close to a center tap of the first inductive element 362. In an exemplary embodiment, the center tap may be connected to a system voltage, VDD.

In an exemplary embodiment, the second element 350 includes a phase shifter 370 coupled between the EM element 361 and the EM element 368. The phase shifter 370 is illustrated as comprising a hybrid quadrature generator (HQG) 380, and variable gain amplifiers (VGAs) 374 and 376, although other implementations of phase shifter may be used. For example, a phase shifter having a polyphase filter and active or passive VGAs may be implemented. In an exemplary embodiment, the HQG 380 may be configured to create an in phase (I) signal and a quadrature (Q) signal separated by 90 degrees. For example, the VGA 374 may be configured to operate on an in phase signal and the VGA 376 may be configured to operate on a quadrature signal. In an exemplary embodiment, a vector modulator driver (VMDR) 366 may be coupled to the EM element 361 and configured to operate on a transmit signal, for example to provide a differential transmit signal to opposite ends of the inductive element 362.

In an exemplary embodiment, outputs of the VGA 374 are provided to opposite sides of the inductive element 372 and outputs of the VGA 376 are provided to opposite sides of the inductive element 372 of the EM element 368. In an exemplary embodiment a switch 377 may be connected between one end of the inductive element 371 and ground, and a switch 378 may be connected between the other end of the inductive element 371 and ground. The switch 377 may be controlled by a control signal Rx_en and the switch 378 may be controlled by a control signal Rx_enb such that when the switch 377 is conductive, the switch 378 is non-conductive and when the switch 378 is conductive, the switch 377 is non-conductive. The complementary control signals Rx_en and Rx_enb may be provided by the data processor (210, FIG. 2C), or by another controller.

In an exemplary embodiment, a transmit (TX) signal may be provided to the VMDR 326 and the VMDR 366 over connections 341a and 341b. In the illustrated example, the TX signal is provided on a connection shared by the elements 310 and 350, but in other examples each of the elements 310 and 350 may be coupled to the same or separate transmit signals over respective connections. In an exemplary embodiment, the TX signal may be a differential signal, but in other embodiments it is a single ended TX signal. Connection 341 may be coupled to the upconverter 240 or 275. In an exemplary embodiment, a transmit path in the element 310 may be indicated using the arrow 344, where in an exemplary embodiment the transmit path 344 comprises the VMDR 326, the EM element 321, the HQG 340, the VGAs 334 and 336, the EM element 328, the driver amplifier 319, the PA 318 and the EM element 312. In an exemplary embodiment, a transmit path in the element 350 may be indicated using the arrow 384, where in an exemplary embodiment the transmit path 384 comprises the VMDR 366, the EM element 361, the HQG 380, the VGAs 374 and 376, the EM element 368, the driver amplifier 359, the PA 358 and the EM element 352.

In an exemplary embodiment, receive signals may be provided over connection 342 to downstream processing elements, e.g., via a phased array output. In an exemplary embodiment, an RX signal may be a differential signal or a single ended signal. In an exemplary embodiment, the receive signal may be a single-ended signal. In the illustrated example, the RX signals are provided on a connection shared by the elements 310 and 350, but in other examples each of the elements 310 and 350 may provide transmit signals over respective connections. Connection 342 may be coupled to the downconverter 260 or 285. In an exemplary embodiment, a receive path in the element 310 may be indicated using the arrow 345, where in an exemplary embodiment the receive path 345 comprises the EM element 312, the LNA 316, the second stage LNA 317, the EM element 321, the HQG 340, the VGAs 334 and 336, the EM element 328 and the connection 342. In an exemplary embodiment, a receive path in the element 350 may be indicated using the arrow 385, where in an exemplary embodiment the receive path 385 comprises the EM element 352, the LNA 356, the second stage LNA 357, the EM element 361, the HQG 380, the VGAs 374 and 376, the EM element 368 and the connection 342. In an exemplary embodiment, the transmit path 344 and the receive path 345 follow a same path (in the same direction) through the phase shifter 320 and the transmit path 384 and the receive path 385 follow a same path (in the same direction) through the phase shifter 370.

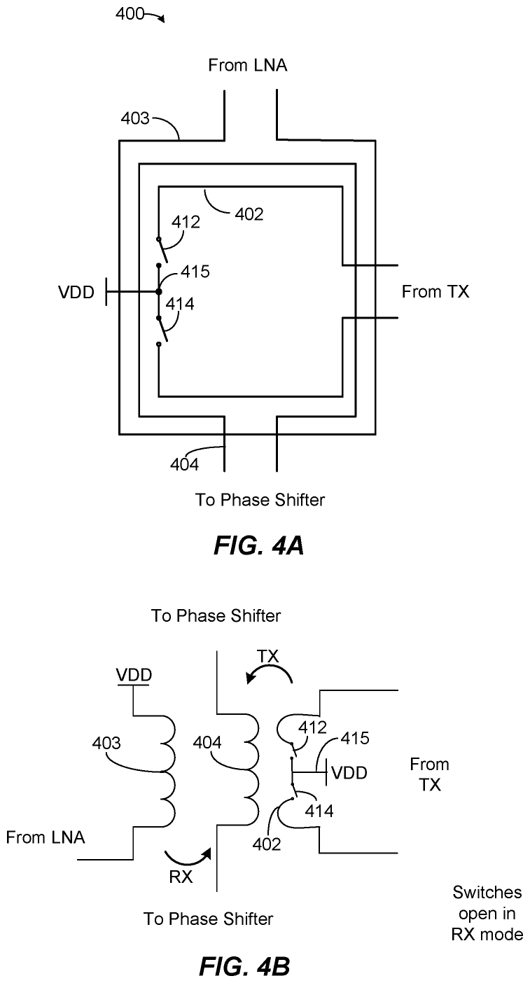

FIGS. 4A and 4B are schematic diagrams of an exemplary embodiment of an embodiment of a tri-coil of FIG. 3. In FIG. 4A, the tri-coil 400 may be an example of the EM element 321 or the EM element 361 of FIG. 3. In an exemplary embodiment, the tri-coil 400 may comprise a first winding 402 coupled to a source of a transmit signal (e.g., via the VMDR 326 or 366), a second winding 403 coupled to an LNA (e.g., the second stage LNA 317 or 357) and a third winding 404 coupled to a phase shifter input (e.g., the phase shifter 320 or 370). In an exemplary embodiment, the first winding 402 may correspond to the first inductive element 322 or 362 (FIG. 3), the second winding 403 may correspond to the second inductive element 323 or 363 (FIG. 3) and the third winding 404 may correspond to the third inductive element 324 or 364 (FIG. 3).

In an exemplary embodiment, the tri-coil 400 also comprises switches 412 and 414 located in the first winding 402. In an exemplary embodiment, the switches 412 and 414 may correspond to the switches 325/365 and 327/367 in FIG. 3. The node 415 between the switches 412 and 414 may be connected to a system voltage, VDD. In an exemplary embodiment, while the first winding 402, the second winding 403 and the third winding 404 are shown as single turn coils having a generally rectangular shape, the first winding 402, the second winding 403 and the third winding 404 can be fabricated using different numbers of turns and can be different shapes, such as, for example, square, hexagonal, octagonal, or other shapes.

In an exemplary embodiment, the switches 412 and 414 may be P-type complementary metal oxide semiconductor (PMOS) switches, but in other embodiments the switches 412 and 414 may be N-type MOS (NMOS) switches or switches fabricated using other manufacturing technologies. In an exemplary embodiment, the switches 412 and 414 may be controlled by a control signal from the data processor 210 or another controller. In an exemplary embodiment, the switches 412 and 414 may be configured to selectively alter an impedance of the first winding 402 when in transmit mode or receive mode. For example, in a receive mode, the switches 412 and 414 may be open so that a high impedance is presented to the second stage LNA 317 (or 357) and HQG 340 (or 380). In a transmit mode, the switches 412 and 414 may be closed so that a transmit signal is transferred from the first winding 402 to the third winding 404.

In an exemplary embodiment, the location of the switches 412 and 414 in the first winding 402 close to the node 415 having the system voltage, VDD, may add little or no parasitic losses to a differential mode signal. Locating the switches 412 and 414 close to the node 415 (e.g., closer to the center tap of the first winding 402 instead of than to the outer terminals of the first winding 402, which connect to the VMDR 326 or 366) reduces or avoids any differential parasitic capacitance from the switches 412 and 414 from loading the VMDR 326 in differential mode.

In an exemplary embodiment, the VMDR 326 and the VMDR 366 operate at sufficiently low current so as to allow the switches 412 and 414 to have a modest resistance of, for example, one (1) to two (2) ohms without incurring a voltage headroom drop that could negatively affect signal quality.

In an exemplary embodiment, when the switches 412 and 414 are located near the node 415, when in a non-conductive state the switch parasitics are resonated out through the inductance of the first winding 402, which helps to maintain the off impedance of the switches 412 and 414 relatively high.

In an exemplary embodiment, the second stage LNA 317 has a very high off impedance, which reduces or minimizes the loading of the second stage LNA 317 presented to the transmit circuitry in the first element 310.

In an exemplary embodiment, in RX mode, the switches 412 and 414 are non-conductive, thus allowing a receive signal to easily pass from the second winding 403 to the third winding 404.

In an exemplary embodiment, in TX mode, the LNA 316 and the second stage LNA 317 are off and the switches 412 and 414 are conductive to facilitate the transmission of a transmit signal from the first winding 402 to the third winding 404.

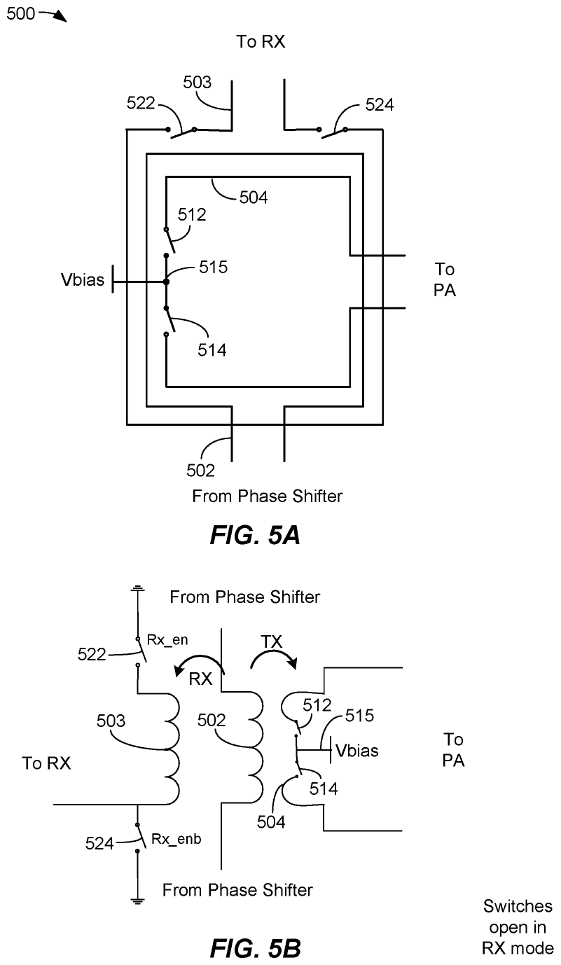

FIGS. 5A and 5B are schematic diagrams of an exemplary embodiment of an embodiment of a tri-coil of FIG. 3. In FIG. 5A, the tri-coil 500 may be an example of the EM element 328 or the EM element 368 of FIG. 3. In an exemplary embodiment, the tri-coil 500 may comprise a first winding 502 coupled to phase shifter output (e.g., the phase shifter 320 or 370), a second winding 503 coupled to a receive network (e.g., the connection 342 and other downstream circuitry) and a third winding 504 coupled to a PA (e.g., the PA 318 or 358, for example via the DA 319 or 359). In an exemplary embodiment, the first winding 502 may correspond to the first inductive element 332 or 372 (FIG. 3), the second winding 503 may correspond to the second inductive element 331 or 371 (FIG. 3) and the third winding 504 may correspond to the third inductive element 329 or 369 (FIG. 3).

In an exemplary embodiment, the tri-coil 500 also comprises switches 512 and 514 located in the third winding 504; and switches 522 and 524 located in the second winding 503. In an exemplary embodiment, the switches 512 and 514 may correspond to the switches 333/373 and 335/375 in FIG. 3, and the switches 522 and 524 may correspond to the switches 337/377 and 338/378. The node 515 between the switches 512 and 514 may be connected to a bias voltage, Vbias. In an exemplary embodiment, while the first winding 502, the second winding 503 and the third winding 504 are shown as single turn coils having a generally rectangular shape, the first winding 502, the second winding 503 and the third winding 504 can be fabricated using different numbers of turns and can be different shapes, such as, for example, square, hexagonal, octagonal, or other shapes.

In an exemplary embodiment, the switches 512 and 514 may be P-type complementary metal oxide semiconductor (PMOS) switches, but in other embodiments the switches 512 and 514 may be N-type MOS (NMOS) switches or switches fabricated using other manufacturing technologies. Similarly, the switches 522 and 524 may be P-type complementary metal oxide semiconductor (PMOS) switches, but in other embodiments the switches 522 and 524 may be N-type MOS (NMOS) switches or switches fabricated using other manufacturing technologies. In an exemplary embodiment, the switches 512, 514, 522 and 524 may be controlled by a control signal from the data processor 210 or another controller to selectively alter an impedance of the second winding 503 and the third winding 504.

In an exemplary embodiment, the location of the switches 512 and 514 in the third winding 504; and the switches 522 and 524 in the second winding 331 may add little or no parasitic losses or loading to a differential mode signal, as described above. In an exemplary embodiment, the switch 522 is located near the lowest differential mode voltage swing point and adds no capacitive parasitic losses to the second winding 503. Optimally, the switch 524 may be sized significantly smaller (⅕th the size or more) than the switch 522 to maintain a desired isolation between the first winding 502 and the second winding 503 in transmit mode, while presenting minimal loading to the second winding 503.

In an exemplary embodiment, there is no DC current on a gate of the driver amplifier 319 (FIG. 3), so that an NMOS switch implemented as the switch 512 and the switch 514 will each operate as a level shifting switch. For example, in TX mode, the switches 512 and 514 will have a drain-source voltage that is the same as the gate-source voltage of the driver amplifier 319 (FIG. 3). Therefore, it will take the gate voltage of VDD plus the gate-source voltage of the driver amplifier 319 (FIG. 3) to turn on the switches 512 and 514.

In an exemplary embodiment, in RX mode, the switches 512 and 514 are non-conductive, the switch 524 is non-conductive and the switch 522 is conductive, thus allowing a receive signal to easily pass from the first winding 502 to the second winding 503. The switches 522 and 524 receive complementary control signals Rx_en and Rx_enb so that they are complementarily controlled.

In an exemplary embodiment, in TX mode, the LNA 316 (or 356) and the second stage LNA 317 (or 357) are off, the switches 512 and 514 are conductive, the switch 524 is conductive and the switch 522 is non-conductive to facilitate the transmission of a transmit signal from the first winding 502 to the third winding 504. The switches 522 and 524 receive complementary control signals Rx_en and Rx_enb so that they are complementarily controlled.

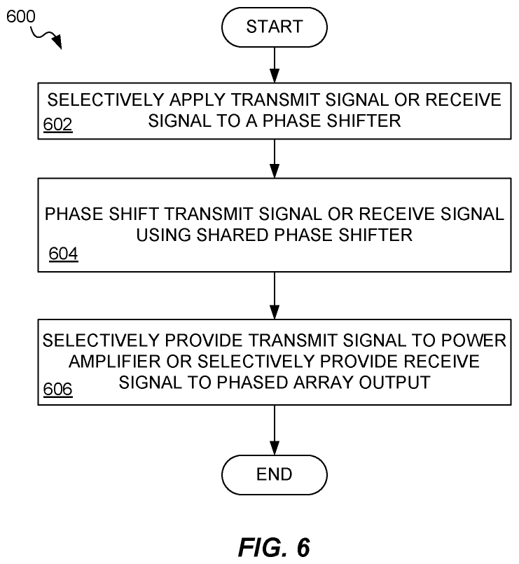

FIG. 6 is a flow chart 600 describing an example of the operation of a method for processing signals. The blocks in the method 600 can be performed in or out of the order shown, and in some embodiments, can be performed at least in part in parallel.

In block 602, a (e.g., mmW) transmit signal or a (e.g., mmW) receive signal is selectively applied to a phase shifter. For example, the EM element 321, which may be configured as a tri-coil, may be configured to apply a transmit signal from the VMDR 326 to the HQG 340 or the EM element 321 may be configured to selectively apply a receive signal from the second stage LNA 317 to the HQG 340.

In block 604, a transmit signal or a receive signal is phase shifted by a shared phase shifter. For example, a transmit signal or a receive signal may be phase shifted by the HQG 340 and the variable gain amplifiers (VGAs) 334 and 336.

In block 606, the phase shifted transmit signal is selectively applied to a power amplifier or the phase shifted receive signal is selectively applied to a phased array output. For example, in a transmit mode, the transmit signal may be applied by the EM element 328, which may be configured as a tri-coil, to the driver amplifier 319, or the receive signal may be selectively applied by the EM element 328 to connection 342 for further processing.

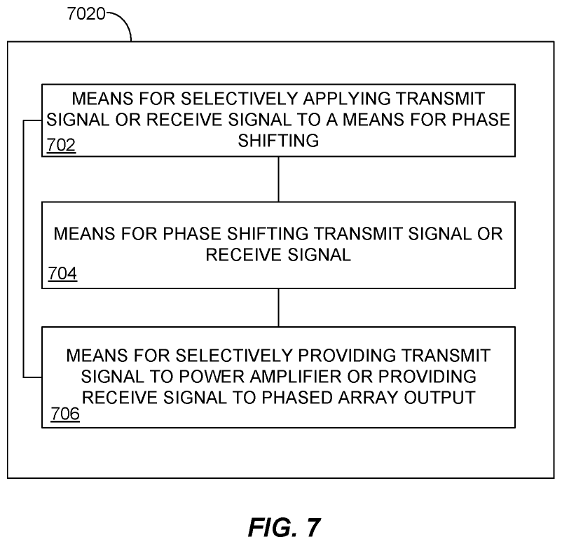

FIG. 7 is a functional block diagram of an apparatus 700 for processing signals. The apparatus 1700 comprises means 702 for selectively applying a transmit signal or a receive signal to means for phase shifting. In certain embodiments, the means 702 for selectively applying a transmit signal or a receive signal to means for phase shifting can be configured to perform one or more of the functions described in operation block 602 of method 600 (FIG. 6). In an exemplary embodiment, the means 702 for selectively applying a transmit signal or a receive signal to means for phase shifting may comprise the EM element 321, which may be configured as a tri-coil.

The apparatus 700 may also comprise shared means 704 for phase shifting the transmit signal or the receive signal. In certain embodiments, the shared means 704 for phase shifting a transmit signal or a receive signal can be configured to perform one or more of the functions described in operation block 604 of method 600 (FIG. 6). In an exemplary embodiment, the shared means 704 for phase shifting a transmit signal or a receive signal may comprise the HQG 340 and the variable gain amplifiers (VGAs) 334 and 336.

The apparatus 700 may also comprise means 706 for selectively applying a transmit signal to a power amplifier or selectively applying a receive signal to a phased array output. In certain embodiments, the means 706 for selectively applying a transmit signal to a power amplifier or selectively applying a receive signal to a phased array output can be configured to perform one or more of the functions described in operation block 606 of method 600 (FIG. 6). In an exemplary embodiment, the means 706 for selectively applying a transmit signal to a power amplifier or selectively applying a receive signal to a phased array output may comprise the EM element 312, which may be configured as a tri-coil.

### Implementation Examples are Described in the Following Numbered Clauses

1. A millimeter wave (mmW) communication system located on a millimeter wave integrated circuit (MMW-IC), comprising: a phase shifter selectively connected to a receive path by a first electromagnetic (EM) element and selectively connected to a transmit path by a second EM element; the first EM element configured to receive a transmit signal and configured to receive a receive signal from a low noise amplifier (LNA); the second EM element configured to receive a phase shifted transmit signal or a phase shifted receive signal from the phase shifter; and wherein the second EM element is configured to selectively provide the phase shifted transmit signal to a power amplifier on the mmW-IC and the phase shifted receive signal to receive signal processing circuitry located off of the mmW-IC.

2. The communication system of clause 1, wherein the first EM element comprises a first winding, a second winding and a third winding, and the first winding comprises switches configured to alter an impedance of the first winding.

3. The communication system of clause 1 or clause 2, wherein the second EM element comprises a first winding, a second winding and a third winding, the second winding comprises switches configured to alter an impedance of the second winding and the third winding comprises switches configured to alter an impedance of the third winding.

4. The communication system of clause 2, wherein in a receive mode the switches in the first winding are configured to be non-conductive to present a high impedance to the second winding and the third winding.

5. The communication system of clause 2, wherein in a transmit mode, the switches in the first winding are configured to be conductive so that a transmit signal is transferred from the first winding to the third winding.

6. The communication system of any of clauses 2, 4 or 5, wherein the switches in the first winding are located near a center tap of the first winding to minimize parasitic losses to a differential mode signal.

7. The communication system of clause 3, wherein in a receive mode, a first switch in the second winding is selectively conductive and a second switch in the second winding is selectively non-conductive and the switches in the third winding are non-conductive allowing a receive signal to pass from the first winding to the second winding.

8. The communication system of clause 3, wherein in a transmit mode a first switch in the second winding is selectively conductive and a second switch in the second winding is selectively non-conductive and the switches in the third winding are conductive to allow a transmit signal to pass from the first winding to the third winding.

9. The communication system of any of clauses 3,7 or 8, wherein the switches in the third winding are located near a center tap of the third winding to minimize parasitic losses to a differential mode signal.

10. A method for phase shifting signals, comprising: selectively applying a transmit signal or a receive signal to a shared phase shifter; phase shifting the transmit signal or the receive signal; and selectively applying the phase shifted transmit signal to a power amplifier or selectively applying the phase shifted receive signal to a phased array output.

11. The method of clause 10, wherein selectively applying the transmit signal or the receive signal to a shared phase shifter comprises impedance matching.

12. The method of any of clauses 10 through 11, wherein selectively applying the receive signal to the shared phase shifter comprises selectively setting switches in a first winding of a first EM element to be non-conductive so that the receive signal passes from a second winding in the first EM element to a third winding in the first EM element.

13. The method of any of clauses 10 through 12, wherein selectively applying the transmit signal to the shared phase shifter comprises selectively setting switches in the first winding of the first EM element to be conductive so that the transmit signal passes from the first winding in the first EM element to the third winding in the first EM element.

14. The method of clause 12, wherein the switches in the first winding of the first EM element are located near a center tap of the first winding to minimize parasitic losses to a differential signal.

15. The method of clause 10, wherein selectively applying the phase shifted receive signal to the phased array output comprises selectively setting complementary switches in a second winding of a second EM element to be conductive and non-conductive and selectively setting switches in a third winding of the second EM element to be non-conductive so that the phase shifted receive signal passes from a first winding in the second EM element to the second winding of the second EM element.

16. The method of clause 15, wherein selectively applying the phase shifted transmit signal to the power amplifier comprises selectively setting the complementary switches in the second winding of the second EM element to be conductive and non-conductive and selectively setting switches in the third winding of the second EM element to be conductive so that the phase shifted transmit signal passes from the first winding in the second EM element to the third winding of the second EM element.

17. The method of any of clauses 15 through 16, wherein the switches in the third winding of the second EM element are located near a center tap of the third winding to minimize parasitic losses to a differential signal.

18. A device for signal phase shifting, comprising: means for selectively applying a transmit signal or a receive signal to a shared phase shifter; means for phase shifting the transmit signal or the receive signal; and means for selectively applying the phase shifted transmit signal to a power amplifier or selectively applying the phase shifted receive signal to a phased array output.

19. The device of clause 18, wherein the means for selectively applying the transmit signal or the receive signal to a shared phase shifter comprises means for impedance matching.

20. The device of any of clauses 18 through 19, wherein the means for selectively applying the receive signal to the shared phase shifter comprises means for selectively setting switches in a first winding of a first EM element to be non-conductive so that the receive signal passes from a second winding in the first EM element to a third winding in the first EM element.

21. The device of any of clauses 18 through 20, wherein the means for selectively applying the transmit signal to the shared phase shifter comprises means for selectively setting switches in a first winding of a first EM element to be conductive so that the transmit signal passes from a first winding in the first EM element to a third winding in the first EM element.

22. The device of clause 20, wherein the switches in the first winding of the first EM element are located near a center tap of the first winding to minimize parasitic losses to a differential signal.

23. The device of clause 18, wherein the means for selectively applying the phase shifted receive signal to the phased array output comprises means for selectively setting complementary switches in a second winding of a second EM element to be conductive and non-conductive and selectively setting switches in a third winding of the second EM element to be non-conductive so that the phase shifted receive signal passes from a first winding in the second EM element to the second winding of the second EM element.

24. The device of clause 18, wherein the means for selectively applying the phase shifted transmit signal to the power amplifier comprises means for selectively setting complementary switches in a second winding of a second EM element to be conductive and non-conductive and selectively setting switches in a third winding of the second EM element to be conductive so that the phase shifted transmit signal passes from a first winding in the second EM element to the third winding of the second EM element.

25. The device of any of clauses 23 through 24, wherein the switches in the third winding of the second EM element are located near a center tap of the third winding to minimize parasitic losses to a differential signal.

26. A phased array element, comprising: receive circuitry; transmit circuitry; a first electromagnetic (EM) element coupled to the receive circuitry; a second EM element coupled to the transmit circuitry; and a phase shifter coupled between the first EM element and the second EM element, wherein the phased array element is configured such that the phase shifter is shared by the receive circuitry and the transmit circuitry.

27. The phased array element of clause 26, wherein the phased array element is configured such that transmit signals and receive signals follow a same path through the phase shifter.

28. The phased array element of any of clauses 26 through 27, wherein the first EM element comprises a first tri-coil and the second EM element comprises a second tri-coil.

29. The phased array element of clause 28, wherein the first EM element is differentially coupled to a hybrid quadrature generator or polyphase filter, the hybrid quadrature generator or polyphase filter is configured to provide quadrature signals to respective variable gain amplifiers, and the variable gain amplifiers are each differentially coupled to the second EM element.

30. The phased array element of clause 29, wherein the second EM element is configured to provide a single-ended receive signal.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A millimeter wave (mmW) communication system located on a millimeter wave integrated circuit (MMW-IC), comprising:
a phase shifter selectively connected to a receive path by a first electromagnetic (EM) element and selectively connected to a transmit path by a second EM element;
the first EM element configured to receive a transmit signal and configured to receive a receive signal from a low noise amplifier (LNA);
the second EM element configured to receive a phase shifted transmit signal or a phase shifted receive signal from the phase shifter; and
wherein the second EM element is configured to selectively provide the phase shifted transmit signal to a power amplifier on the mmW-IC and the phase shifted receive signal to receive signal processing circuitry located off of the mmW-IC.

2. The communication system of claim 1, wherein the first EM element comprises a first winding, a second winding and a third winding, and the first winding comprises switches configured to alter an impedance of the first winding.

3. The communication system of claim 1, wherein the second EM element comprises a first winding, a second winding and a third winding, the second winding comprises switches configured to alter an impedance of the second winding and the third winding comprises switches configured to alter an impedance of the third winding.

4. The communication system of claim 2, wherein in a receive mode the switches in the first winding are configured to be non-conductive to present a high impedance to the second winding and the third winding.

5. The communication system of claim 2, wherein in a transmit mode, the switches in the first winding are configured to be conductive so that a transmit signal is transferred from the first winding to the third winding.

6. The communication system of claim 2, wherein the switches in the first winding are located near a center tap of the first winding to minimize parasitic losses to a differential mode signal.

7. The communication system of claim 3, wherein in a receive mode, a first switch in the second winding is selectively conductive and a second switch in the second winding is selectively non-conductive and the switches in the third winding are non-conductive allowing a receive signal to pass from the first winding to the second winding.

8. The communication system of claim 3, wherein in a transmit mode a first switch in the second winding is selectively conductive and a second switch in the second winding is selectively non-conductive and the switches in the third winding are conductive to allow a transmit signal to pass from the first winding to the third winding.

9. The communication system of claim 3, wherein the switches in the third winding are located near a center tap of the third winding to minimize parasitic losses to a differential mode signal.

10. A method for phase shifting signals, comprising:
selectively applying a transmit signal or a receive signal to a shared phase shifter;
phase shifting the transmit signal or the receive signal; and
selectively applying the phase shifted transmit signal to a power amplifier or selectively applying the phase shifted receive signal to a phased array output.

11. The method of claim 10, wherein selectively applying the transmit signal or the receive signal to a shared phase shifter comprises impedance matching.

12. The method of claim 10, wherein selectively applying the receive signal to the shared phase shifter comprises selectively setting switches in a first winding of a first EM element to be non-conductive so that the receive signal passes from a second winding in the first EM element to a third winding in the first EM element.

13. The method of claim 12, wherein selectively applying the transmit signal to the shared phase shifter comprises selectively setting switches in the first winding of the first EM element to be conductive so that the transmit signal passes from the first winding in the first EM element to the third winding in the first EM element.

14. The method of claim 12, wherein the switches in the first winding of the first EM element are located near a center tap of the first winding to minimize parasitic losses to a differential signal.

15. The method of claim 10, wherein selectively applying the phase shifted receive signal to the phased array output comprises selectively setting complementary switches in a second winding of a second EM element to be conductive and non-conductive and selectively setting switches in a third winding of the second EM element to be non-conductive so that the phase shifted receive signal passes from a first winding in the second EM element to the second winding of the second EM element.

16. The method of claim 15, wherein selectively applying the phase shifted transmit signal to the power amplifier comprises selectively setting the complementary switches in the second winding of the second EM element to be conductive and non-conductive and selectively setting switches in the third winding of the second EM element to be conductive so that the phase shifted transmit signal passes from the first winding in the second EM element to the third winding of the second EM element.

17. The method of claim 15, wherein the switches in the third winding of the second EM element are located near a center tap of the third winding to minimize parasitic losses to a differential signal.

18. A device for signal phase shifting, comprising:
means for selectively applying a transmit signal or a receive signal to a shared phase shifter;
means for phase shifting the transmit signal or the receive signal; and
means for selectively applying the phase shifted transmit signal to a power amplifier or selectively applying the phase shifted receive signal to a phased array output.

19. The device of claim 18, wherein the means for selectively applying the transmit signal or the receive signal to a shared phase shifter comprises means for impedance matching.

20. The device of claim 18, wherein the means for selectively applying the receive signal to the shared phase shifter comprises means for selectively setting switches in a first winding of a first EM element to be non-conductive so that the receive signal passes from a second winding in the first EM element to a third winding in the first EM element.

21. The device of claim 18, wherein the means for selectively applying the transmit signal to the shared phase shifter comprises means for selectively setting switches in a first winding of a first EM element to be conductive so that the transmit signal passes from a first winding in the first EM element to a third winding in the first EM element.

22. The device of claim 20, wherein the switches in the first winding of the first EM element are located near a center tap of the first winding to minimize parasitic losses to a differential signal.

23. The device of claim 18, wherein the means for selectively applying the phase shifted receive signal to the phased array output comprises means for selectively setting complementary switches in a second winding of a second EM element to be conductive and non-conductive and selectively setting switches in a third winding of the second EM element to be non-conductive so that the phase shifted receive signal passes from a first winding in the second EM element to the second winding of the second EM element.

24. The device of claim 18, wherein the means for selectively applying the phase shifted transmit signal to the power amplifier comprises means for selectively setting complementary switches in a second winding of a second EM element to be conductive and non-conductive and selectively setting switches in a third winding of the second EM element to be conductive so that the phase shifted transmit signal passes from a first winding in the second EM element to the third winding of the second EM element.

25. The device of claim 23, wherein the switches in the third winding of the second EM element are located near a center tap of the third winding to minimize parasitic losses to a differential signal.

26. A phased array element, comprising:
receive circuitry;
transmit circuitry;
a first electromagnetic (EM) element coupled to the receive circuitry;
a second EM element coupled to the transmit circuitry; and
a phase shifter coupled between the first EM element and the second EM element,
wherein the phased array element is configured such that the phase shifter is shared by the receive circuitry and the transmit circuitry.

27. The phased array element of claim 26, wherein the phased array element is configured such that transmit signals and receive signals follow a same path through the phase shifter.

28. The phased array element of claim 26, wherein the first EM element comprises a first tri-coil and the second EM element comprises a second tri-coil.

29. The phased array element of claim 28, wherein the first EM element is differentially coupled to a hybrid quadrature generator or polyphase filter, the hybrid quadrature generator or polyphase filter is configured to provide quadrature signals to respective variable gain amplifiers, and the variable gain amplifiers are each differentially coupled to the second EM element.

30. The phased array element of claim 29, wherein the second EM element is configured to provide a single-ended receive signal.
